(19) United States
(12) Patent Application Publication
(10) Pub. No.: US 2025/0260374 A1
(43) Pub. Date: Aug. 14, 2025

(54) DIFFERENTIAL AMPLIFIER CIRCUITRY WITH COARSE AND FINE GAIN TRIM

(71) Applicant: TEXAS INSTRUMENTS INCORPORATED, Dallas, TX (US)

(72) Inventors: Ravinthiran BALASINGAM, Tucson, AZ (US); Ankit KHANNA, Tucson, AZ (US); Dimitar TRIFONOV, Vail, AZ (US)

(21) Appl. No.: 18/737,453

(22) Filed: Jun. 7, 2024

Related U.S. Application Data
(60) Provisional application No. 63/553,158, filed on Feb. 14, 2024.

(51) Int. Cl. H03F 3/45; H03F 1/26; H03G 3/30

(52) U.S. Cl. CPC H03F 3/45264; H03F 1/26; H03G 3/30; H03F 2203/45702

(57) ABSTRACT

An integrated circuit includes differential amplifier circuitry. The differential amplifier circuitry includes: first gain trim circuitry having a first gain trim input, the first gain trim circuitry including a first differential input transistor pair and a second differential input transistor pair; second gain trim circuitry having a second gain trim input, the second gain trim circuitry including a third differential input transistor pair and a fourth differential input transistor pair; and control logic having a first gain trim output and a second gain trim output. The first gain trim output is coupled to the first gain trim input. The second gain trim output is coupled to the second gain trim input.

### CROSS-REFERENCE TO RELATED APPLICATIONS

The present application claims priority to U.S. Provisional Application No. 63/553,158, titled “CIRCUIT FOR AMPLIFIER WITH INTEGRATED DAC ENABLING COURSE AND FINE GAIN TUNING”, Attorney Docket number T104083US01, filed on Feb. 14, 2024, which is hereby incorporated by reference in its entirety.

### BACKGROUND

Closed loop amplifiers are often used to amplify a differential input voltage with a fixed gain, resulting in an output voltage. Dynamic amplifier gain adjustments would expand compatibility with a range of input signals and reduce gain error due to changes (e.g., temperature change, aging of components, etc.). The complexity, the cost, and/or the limited accuracy of dynamic amplifier gain adjustment circuitry are ongoing challenges.

### SUMMARY

In an example, an integrated circuit includes differential amplifier circuitry. The differential amplifier circuitry includes: first gain trim circuitry having a first gain trim input, the first gain trim circuitry including a first differential input transistor pair and a second differential input transistor pair; second gain trim circuitry having a second gain trim input, the second gain trim circuitry including a third differential input transistor pair and a fourth differential input transistor pair; and control logic having a first gain trim output and a second gain trim output. The first gain trim output is coupled to the first gain trim input. The second gain trim output is coupled to the second gain trim input.

In another example, a differential amplifier circuit includes: first differential input transistor pairs; second differential input transistor pairs; resistor pairs; first selection circuitry having a first control input, the first selection circuitry coupled between the resistor pairs and the first differential input transistor pairs; second selection circuitry having a second control input, the second selection circuitry coupled between the set of resistor pairs and the second differential input transistor pairs; and control logic having a first gain trim output and a second gain trim output, the first gain trim output coupled to the first control input, and the second gain trim output coupled to the second control input.

In yet another example, an apparatus includes differential amplifier circuitry. The differential amplifier circuitry includes: first gain trim circuitry; second gain trim circuitry; and control logic coupled to the coarse gain trim circuitry and the fine gain trim circuitry. The control logic is configured to: receive control inputs; determine a gain setting based on the control inputs; adjust a setting of the first gain trim circuitry responsive to the gain setting; and adjust a setting of the second gain trim circuitry responsive to the gain setting.

### BRIEF DESCRIPTION OF THE DRAWINGS

FIG. 1 is a diagram showing an example system.

FIG. 2 is a diagram showing another example system.

FIG. 3A is a schematic diagram showing example differential amplifier circuitry.

FIG. 3B is a schematic diagram showing other differential amplifier circuitry.

FIG. 4 is a block diagram showing example differential amplifier circuitry.

FIG. 5 is a schematic diagram showing example gain trim circuitry.

FIG. 6 is a schematic diagram showing other example gain trim circuitry.

FIG. 7 is a diagram showing example differential amplifier circuitry.

FIG. 8 is a flowchart showing an example gain trim control method.

### DETAILED DESCRIPTION

The same reference numbers or other reference designators are used in the drawings to designate the same or similar features. Such features may be the same or similar either by function and/or structure.

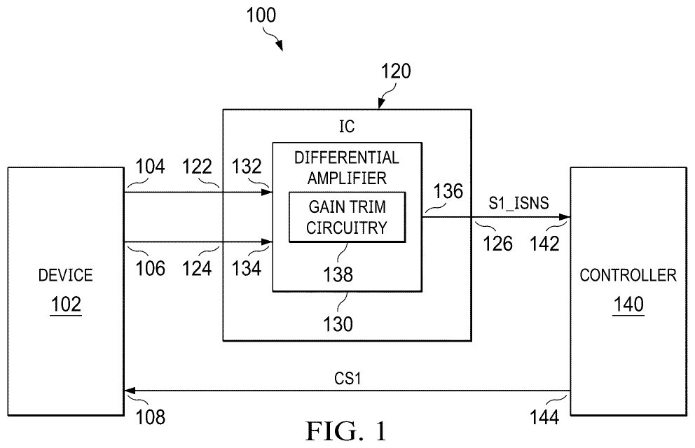

FIG. 1 is a diagram showing an example system 100. In different examples, the system 100 is part of an overvoltage protection system, a battery management system, a power telemetry system, a motor control system, or a solenoid control system. As shown, the system 100 includes an electrical device 102, an integrated circuit (IC) 120, and a controller 140. In different examples, the electrical device 102 may be a battery, a motor, a solenoid, a telemetry device, a power regulation device, a sensor, or other electrical device. In the example of FIG. 1, the electrical device 102 has a first terminal 104, a second terminal 106, and third terminal 108. If the electrical device 102 is a sensor, the third terminal 108 may be omitted. The IC 120 has a first terminal 122, a second terminal 124, and a third terminal 126. The controller 140 has a first terminal 142 and a second terminal 144.

In the example of FIG. 1, the IC 120 includes differential amplifier circuitry 130 with gain trim circuitry 138. The differential amplifier circuitry 130 has a first terminal 132, a second terminal 134, and a third terminal 136. In the example of FIG. 1, the first terminal 104 of the electrical device 102 is coupled to the first terminal 122 of the IC 120. The second terminal 106 of the electrical device 102 is coupled to the second terminal 124 of the IC 120. The third terminal 126 of the IC 120 is coupled to the first terminal 142 of the controller 140. The second terminal 144 of the controller 140 is coupled to the third terminal 108 of the electrical device 102. The first terminal 122 of the IC 120 is coupled to the first terminal 132 of the differential amplifier circuitry 130. The second terminal 124 of the IC 120 is coupled to the second terminal 134 of the differential amplifier circuitry 130. The third terminal 126 of the IC 120 is coupled to the third terminal 136 of the differential amplifier circuitry 130.

In some examples, the electrical device 102 operates to: receive a control signal CS1 at the third terminal 108; and perform an operation responsive to the control signal CS1. In other examples, the electrical device 102 does not need the control signal CS1 to perform operations. During operations of the electrical device 102, there is a voltage differential across the first terminal 104 and the second terminal 106 of the electrical device 102. The voltage differential is received at the first and second terminals 122 and 124 of the IC 120, and at the first and second terminals 132 and 134 of the differential amplifier circuitry 130. The differential amplifier circuitry 130 operates to: receive the differential voltage across the first and second terminals 132 and 134; apply a gain to the differential voltage; and provide a sense signal SNS1 at the third terminal 136 responsive to the differential voltage and the gain. In some examples, the gain of the differential amplifier circuitry 130 is adjustable using the gain trim circuitry 138. In some examples, the gain trim circuitry 138 provides coarse gain trim levels and a fine gain trim levels. To improve accuracy, the gain trim circuitry 138 may include chopping amplifier components, which reduces the effects of temperature drift and noise.

The controller 140 operates to: receive the sense signal SNS1 at the first terminal 142; and adjust the control signal CS1 responsive to the sense signal SNS1. In some examples, the process of monitoring the differential voltage, providing the sense signal SNS1 to the controller 140, and adjusting the control signal CS1 is repeated to provide ongoing overvoltage protection, ongoing battery management, ongoing power telemetry, ongoing motor control, ongoing solenoid control, ongoing power regulation, or other system operations. The control signal CS1 may be provided to the electrical device 102, as in FIG. 1, or may be provided to another electrical device.

With the gain trim circuitry 138, the gain of the differential amplifier circuitry 130 is adjustable. In some examples, the gain trim circuitry 138 enables coarse gain adjustments and fine gain adjustments. The coarse gain adjustments may be used to cover a target range of gain values. The fine gain adjustments may be used to provide a target gain accuracy. In some examples, the gain trim circuitry 138 includes chopper circuitry. With chopper circuitry, error of the differential amplifier circuitry 130 is reduced. Such error may be due to offset voltage (e.g., due to component mismatch), temperature drift, gain drift and noise (flicker noise). In some examples, the gain trim circuitry 138 includes control logic for selecting between different gain adjustment options and/or chopper options responsive to user input and/or monitored parameters (e.g., an input signal range, a temperature, and/or other monitored parameters).

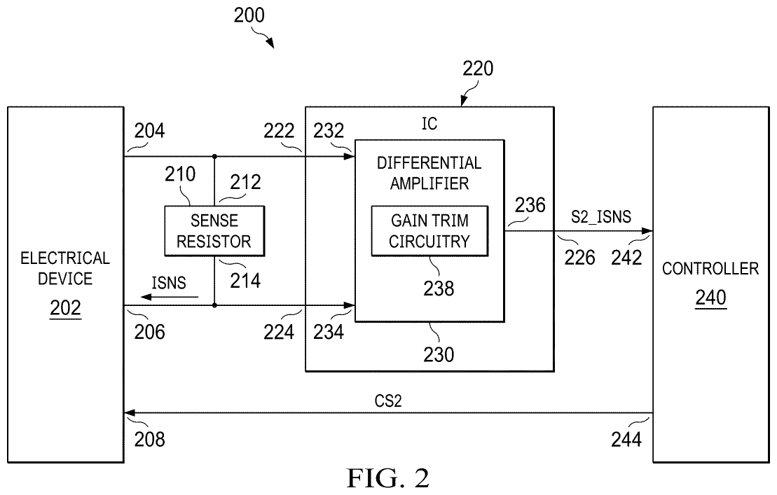

FIG. 2 is a diagram showing another example system. In different examples, the system 200 is part of an overvoltage protection system, a battery management system, a power telemetry system, a motor control system, or a solenoid control system. As shown, the system 200 includes an electrical device 202, a sense resistor 210, an IC 220, and a controller 240. In different examples, the electrical device 202 may be a battery, a motor, a solenoid, a telemetry device, a power regulation device, a sensor, or other electrical device. In the example of FIG. 2, the electrical device 202 has a first terminal 204, a second terminal 206, and third terminal 208. The sense resistor 210 has a first terminal 212 and a second terminal 214. The IC 220 has a first terminal 222, a second terminal 224, and a third terminal 226. The controller 240 has a first terminal 242 and a second terminal 244.

In the example of FIG. 2, the IC 220 includes differential amplifier circuitry 230 with gain trim circuitry 238. The differential amplifier circuitry 230 has a first terminal 232, a second terminal 234, and a third terminal 236. In the example of FIG. 2, the first terminal 204 of the electrical device 202 is coupled to the first terminal 212 of the sense resistor 210 and the first terminal 222 of the IC 220. The second terminal 206 of the electrical device 202 is coupled to the second terminal 214 of the sense resistor 210 and the second terminal 224 of the IC 220. The third terminal 226 of the IC 220 is coupled to the first terminal 242 of the controller 240. The second terminal 244 of the controller 240 is coupled to the third terminal 208 of the electrical device 202.

The first terminal 222 of the IC 220 is coupled to the first terminal 232 of the differential amplifier circuitry 230. The second terminal 224 of the IC 220 is coupled to the second terminal 234 of the differential amplifier circuitry 230. The third terminal 226 of the IC 220 is coupled to the third terminal 236 of the differential amplifier circuitry 230.

In some examples, the electrical device 202 operates to: receive a control signal CS2 at the third terminal 208; and perform an operation responsive to the control signal CS2. During operations of the electrical device 202, a current ISNS flows from the first terminal 204 and through the sense resistor 210. In the example of FIG. 2, the current ISNS flows back to the second terminal 206 of the electrical device 202. In other examples, the current ISNS flows to a ground terminal. In either case, the current ISNS is monitored by the IC 220. In some examples, the differential amplifier circuitry 230 monitors the current ISNS by monitoring a voltage drop across the sense resistor 210. In such examples, the differential amplifier circuitry 230 operates to: receive a first voltage level at the first terminal 232; receive a second voltage level at the second terminal 234; and provide a current sense signal S2_ISNS at the third terminal 236 responsive to the first voltage level and the second voltage level. The controller 240 operates to: receive the current sense signal S2_ISNS at the first terminal 242; and adjust the control signal CS2 responsive to the current sense signal S2_ISNS. In some examples, the process of monitoring the current ISNS using the sense resistor 210 and the differential amplifier circuitry 230, providing the current sense signal S2_ISNS to the controller 240, and adjusting the control signal CS2 for the electrical device 202 is repeated to provide ongoing overcurrent protection, ongoing battery management, ongoing power telemetry, ongoing motor control, ongoing solenoid control, ongoing power regulation, or other system operations.

With the gain trim circuitry 238, the gain of the differential amplifier circuitry 230 is adjustable. In some examples, the gain trim circuitry 238 enables coarse gain adjustments and fine gain adjustments. As another option, the gain trim circuitry 238 includes chopper circuitry. In some examples, the gain trim circuitry 238 includes control logic for selecting between different gain adjustment options and/or chopper options responsive to user input and/or monitored parameters (e.g., an input signal range, a temperature, and/or other monitored parameters).

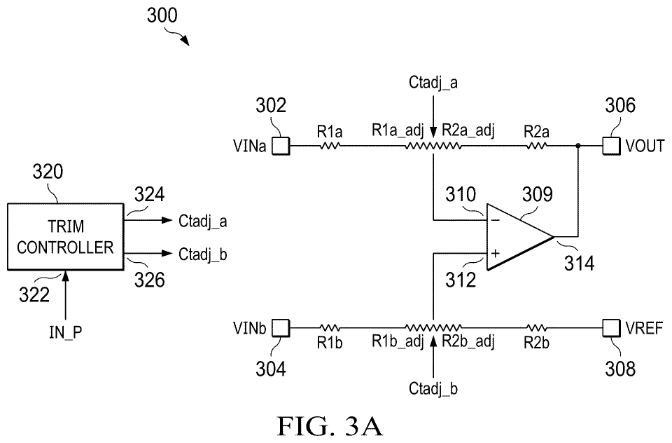

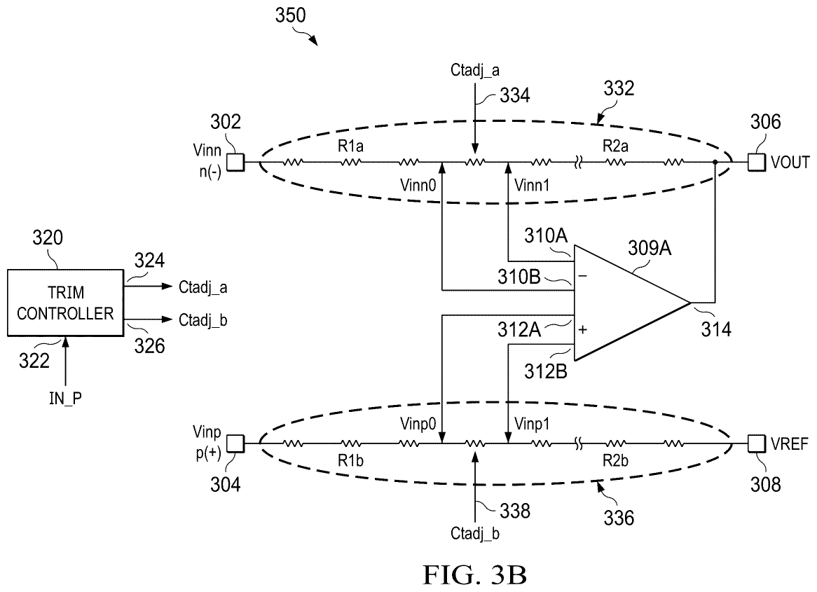

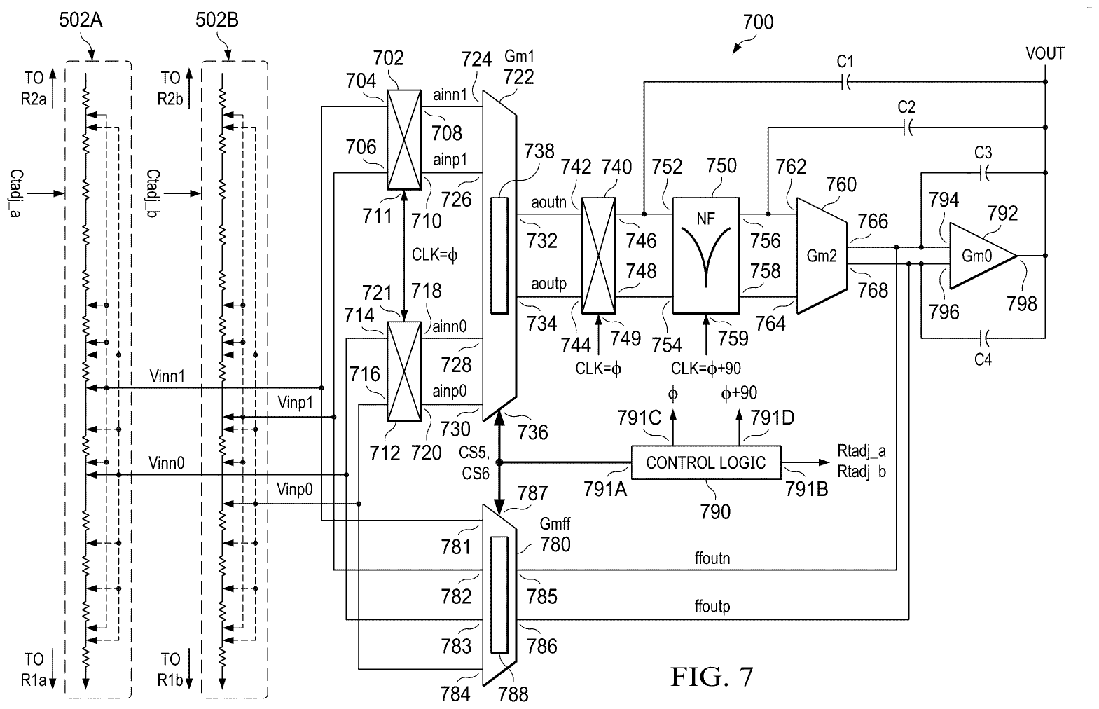

FIG. 3A is a schematic diagram showing example differential amplifier circuitry 300. The differential amplifier circuitry 300 is an example of the differential amplifier circuitry 130 in FIG. 1, or the differential amplifier circuitry 230 in FIG. 2. In some examples, the differential amplifier circuitry 300 may have a chopper amplifier architecture as in differential amplifier circuitry 700 of FIG. 7. In the example of FIG. 3A, the differential amplifier circuitry 300 has a first terminal 302, a second terminal 304, a third terminal 306, and a fourth terminal 308. The differential amplifier circuitry 300 includes an operational amplifier 309, a trim controller 320, and resistors R1a, R1a_adj, R2a_adj, R2a, R1b, R1b_adj, R2b_adj, and R2b in the arrangement shown.

The trim controller 320 has a first terminal 322, a second terminal 324, and a third terminal 326. The operational amplifier 309 has a first (inverting or “−”) terminal 310, a second (non-inverting or “+”) terminal 312, and a third terminal 314. Each of the resistors R1a, R1a_adj, R2a_adj, R2a, R1b, R1b_adj, R2b_adj, and R2b has a respective first terminal and a respective second terminal. The resistors R1a_adj and R2a_adj form a trimmable resistor controlled by a control signal Ctadj_a. In some examples, the value of R1a_adj is inversely proportional to R2a_adj. In other words, when the control signal Ctadj_a increases R1a_adj, R2a_adj is reduced by the same amount such that the total value of R1a_adj+R2a_adj stays constant. Similarly, when the control signal Ctadj_a decreases R1a_adj, R2a_adj is increased by the same amount such that the total value of R1a_adj+R2a_adj stays constant. Also, the resistors R1b_adj and R2b_adj form a trimmable resistor controlled by a control signal Ctadj_b. The value of R1b_adj is inversely proportional to R2b_adj. In other words, when the control signal Ctadj_b increases R1b_adj, R2b_adj is reduced by the same amount such that the total value of R1b_adj+R2b_adj stays constant. Similarly, when the control signal Ctadj_b decreases R1b_adj, R2b_adj is increased by the same amount such that the total value of R1b_adj+R2b_adj stays constant.

In the example of FIG. 3A, the first terminal 302 of the differential amplifier circuitry 300 is coupled to the first terminal of the resistor R1a. The second terminal of the resistor R1a is coupled to the first terminal of the resistor R1a_adj. The second terminal of the resistor R1a_adj is coupled to the first terminal of the resistor R2a_adj and the first terminal 310 of the operational amplifier 309. The second terminal of the resistor R2a_adj is coupled to the first terminal of the resistor R2a. The second terminal of the resistor R2a is coupled to the third terminal 314 of the operational amplifier 309 and the third terminal 306 of the differential amplifier circuitry 300.

In the example of FIG. 3A, the second terminal 304 of the differential amplifier circuitry 300 is coupled to the first terminal of the resistor R1b. The second terminal of the resistor R1b is coupled to the first terminal of the resistor R1b_adj. The second terminal of the resistor R1b_adj is coupled to the first terminal of the resistor R2b_adj and the second terminal 312 of the operational amplifier 309. The second terminal of the resistor R2b_adj is coupled to the first terminal of the resistor R2b. The second terminal of the resistor R2b is coupled to the fourth terminal 308 of the differential amplifier circuitry 300. The second terminal 324 of the trim controller 320 is coupled to the control terminal for the trimmable resistor related to the resistors R1a_adj and R2a_adj. The third terminal 326 of the trim controller 320 is coupled to the control terminal for the trimmable resistor related to the resistors R1b_adj and R2b_adj.

In the example of FIG. 3A, the differential amplifier circuitry 300 operates to: receive a first input voltage VINa at the first terminal 302; receive a second input voltage VINb at the second terminal 304; and provide an output voltage VOUT at the third terminal 306 responsive to operations of the operational amplifier 309, the resistive network formed by the resistors R1a, R1a_adj, R2a_adj, R2a, R1b, R1b_adj, R2b_adj, and R2b, and operations of the trim controller 320. In some examples, a reference voltage VREF is applied at the fourth terminal 308. Specifically, the resistive network formed by the resistors R1a, R1a_adj, R2a_adj, R2a, R1b, R1b_adj, R2b_adj, and R2b determines the gain of the differential amplifier circuitry 300, where the gain is adjustable by the trim controller 320 using the control signals Ctadj_a and Ctadj_b. In some examples, the gain of the differential amplifier circuitry 300 is given as:

$$gain = \frac{( V OUT - V REF )}{( V INb - V INa )} = \frac{( R 2 + R 2 \_adj )}{( R 1 + R 1 \_adj )} = \frac{( R 2 S )}{( R 1 S )} ,$$

where R1=R1a or R1b, R2=R2a or R2b, R2S is R2a adj+R2a or R2b_adj+R2b, and R1S is R1a+R1a_adj or R1b or R2b_adj.

The trim controller 320 operates to: receive input parameters IN_P at the first terminal 322; provide the control signal Ctadj_a at the second terminal 324 responsive to the input parameters IN_P; and provide the control signal Ctadj_b at the third terminal 326 responsive to the input parameters IN_P. In some examples, the input parameters IN_P include a user input to set the gain to a target value. In some examples, the gain is proportional to ((VOUT−VREF)/(VINb−VINa))=((R2+R2_adj)/(R1+R1_adj))=R2S/R1S. In some examples, Ctadj_a and Ctadj_b may be used for coarse trim adjustments and/or fine trim adjustments of the trim controller 320.

With the trim controller 320, the gain of the differential amplifier circuitry 300 is adjustable. In some examples, the trim controller 320 enables coarse gain adjustments and fine gain adjustments. As another option, operational amplifier 309 may include chopper circuitry and the trim controller 320 includes chopper control circuitry. In some examples, the trim controller 320 includes control logic for selecting between different gain adjustment options and/or chopper options responsive to user input and/or monitored parameters (e.g., an input signal range, a temperature, and/or other monitored parameters).

FIG. 3B is a schematic diagram showing other differential amplifier circuitry 350. The differential amplifier circuitry 350 is an example of the differential amplifier circuitry 130 in FIG. 1, the differential amplifier circuitry 230 in FIG. 2, or the differential amplifier circuitry 300 in FIG. 1n some examples, the differential amplifier circuitry 350 may have a chopper amplifier architecture as in differential amplifier circuitry 700 of FIG. 7. In the example of FIG. 3B, the differential amplifier circuitry 350 has the first terminal 302, the second terminal 304, the third terminal 306, the fourth terminal 308, and the trim controller 320 described in FIG. 3A. In the example of FIG. 3B, the first terminal 302 is a “n” (−) terminal that receives Vinn, and the second terminal 304 is a “p”(+) terminal that receives Vinp. The differential amplifier circuitry 350 also includes an operational amplifier 309A, a first resistive network 332, and a second resistive network 336 in the arrangement shown. More specifically, the first resistive network 332 is between the first terminal 302 and the third terminal 306. The second resistive network 336 is between the second terminal 304 and the fourth terminal 308.

The trim controller 320 has the first terminal 322, the second terminal 324, and the third terminal 326. The operational amplifier 309A has first (inverting or “−”) terminals 310A and 310B, second (non-inverting or “+”) terminals 312A and 312B, and the third terminal 314. The first resistive network 332 has a control terminal 334 and includes series resistors includes resistor R1a, resistor R2a, and other resistors. The second resistive network 336 has a control terminal 338 and includes series resistors includes resistor R1b, resistor R2b, and other resistors. The first resistive network 332 couples terminals of one of its series resistors to respective first terminals 310A and 310B of the differential amplifier 309A responsive to Ctadj_a. The second resistive network 336 couples terminals of one of its series resistors to respective second terminals 312A and 312B of the differential amplifier 309A responsive to Ctadj_b.

In the example of FIG. 3B, the differential amplifier circuitry 350 operates to: receive a first input voltage Vinn at the first terminal 302; receive a second input voltage Vinp at the second terminal 304; and provide an output voltage VOUT at the third terminal 306 responsive to operations of the operational amplifier 309A, the resistive network formed by first and second resistive networks 332 and 336, and operations of the trim controller 320. In some examples, a reference voltage VREF is applied at the fourth terminal 308. The first and second resistive networks 332 and 336 determine the gain of the differential amplifier circuitry 350, where the gain is adjustable by the trim controller 320 using the control signals Ctadj_a and Ctadj_b. In some examples, the gain of the differential amplifier circuitry 350 is given as:

$$gain = \frac{( R 2 )}{( R 1 )} = \frac{( R 2 a )}{( R 1 a )} = \frac{( R 2 b )}{( R 1 b )} .$$

In some examples, the trim controller 320 operates to: receive input parameters IN_P at the first terminal 322; provide the control signal Ctadj_a at the second terminal 324 responsive to the input parameters IN_P; and provide the control signal Ctadj_b at the third terminal 326 responsive to the input parameters IN_P. In some examples, the input parameters IN_P include a user input to set the gain to a target value. In some examples, Ctadj_a and Ctadj_b may be used for coarse trim adjustments and/or fine trim adjustments of the trim controller 320.

With the trim controller 320, the gain of the differential amplifier circuitry 300 is adjustable. In some examples, the trim controller 320 enables coarse gain adjustments and fine gain adjustments. As another option, operational amplifier 309 may include chopper circuitry and the trim controller 320 includes chopper control circuitry. In some examples, the trim controller 320 includes control logic for selecting between different gain adjustment options and/or chopper options responsive to user input and/or monitored parameters (e.g., an input signal range, a temperature, and/or other monitored parameters).

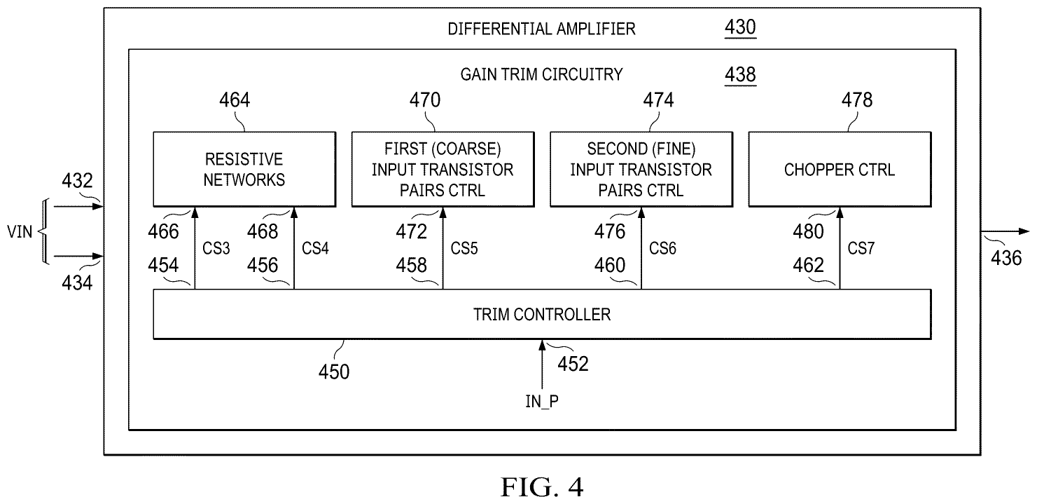

FIG. 4 is a block diagram showing example differential amplifier circuitry 430. The differential amplifier circuitry 430 is an example of the differential amplifier circuitry 130 in FIG. 1, the differential amplifier circuitry 230 in FIG. 2, the differential amplifier circuitry 300 in FIG. 3A, or the differential amplifier circuitry 350 in FIG. 3B. In the example of FIG. 4, the differential amplifier circuitry 430 has a first terminal 432, a second terminal 434, and a third terminal 436. The differential amplifier circuitry 430 includes gain trim circuitry 438. The gain trim circuitry 438 includes a trim controller 450, resistive networks 464, first differential input transistor pairs control circuitry 470, second differential input transistor pairs control circuitry 474, and chopper control circuitry 478.

In the example of FIG. 4, the trim controller 450 has a first terminal 452, a second terminal 454, a third terminal 456, a fourth terminal 458, a fifth terminal 460, and a sixth terminal 462. The resistive networks 464 have a first terminal 466 and a second terminal 468. The first differential input transistor pairs control circuitry 470 has a terminal 472. The second differential input transistor pairs control circuitry 474 has a terminal 476. The chopper control circuitry 478 has a terminal 480.

In the example of FIG. 4, the second terminal 454 of the trim controller 450 is coupled to the first terminal 466 of the resistive networks 464. The third terminal 456 of the trim controller 450 is coupled to the second terminal 468 of the resistive networks 464. The fourth terminal 458 of the trim controller 450 is coupled to the terminal 472 of the first differential input transistor pairs control circuitry 470. The fifth terminal 460 of the trim controller 450 is coupled to the terminal 476 of the second differential input transistor pairs control circuitry 474. The sixth terminal 462 of the trim controller 450 is coupled to the terminal 480 of the chopper control circuitry 478.

In the example of FIG. 4, the trim controller 450 operates to: receive input parameters IN_P at the first terminal 452; provide a control signal CS3 at the second terminal 454 responsive to the input parameters IN_P; provide a control signal CS4 at the third terminal 456 responsive to the input parameters IN_P; provide a control signal CS5 at the fourth terminal 458 responsive to the input parameters IN_P; provide a control signal CS6 at the fifth terminal 460 responsive to the input parameters IN_P; and provide a control signals CS7 at the sixth terminal 462 responsive to the input parameters IN_P.

In some examples, the resistive networks 464 operates to: receive the control signal CS3 at the first terminal 466; receive the control signal CS4 at the second terminal 468; and select resistor pairs responsive to the control signals CS3 and CS4. In some examples, the resistive networks 464 selects the values of the resistors R1a_adj, R2a_adj, R1b_adj, and R2b_adj responsive to the control signals CS3 and CS4. In some examples, CS3 includes the control signal Ctadj_a described herein, and CS4 includes the control signal Ctadj_b described herein.

In some examples, the first differential input transistor pairs control circuitry 470 operates to: receive the control signal CS5 at the terminal 472; and select a differential input transistor pair of the first differential input transistor pairs responsive to the control signal CS5. In some examples, the first differential input transistor pairs control circuitry 470 selects a coarse gain adjustment for the differential amplifier circuitry 430 responsive to the control signal CS5.

In some examples, the second differential input transistor pairs control circuitry 474 operates to: receive the control signal CS6 at the terminal 476; and select a differential input transistor pair of the second differential input transistor pairs responsive to the control signal CS6. In some examples, the second differential input transistor pairs control circuitry 474 selects a fine gain adjustment for the differential amplifier circuitry 430 responsive to the control signal CS6.

In some examples, the chopper control circuitry 478 operates to: receive the control signals CS7 at the terminal 480; and direct chopper operations responsive the control signals CS7. In some examples, the control signals CS7 include a first clock signal (e.g., 0 herein) and a shifted clock signal (e.g., ϕ+90 herein). In some examples, the chopper control circuitry 478 may control cross-coupled switches (e.g., the first, second, and third cross-coupled switches 702, 712, and 740 in FIG. 7) and a notch filter (e.g., the notch filters 750 in FIG. 7) to reduce offset voltage, temperature drift and noise.

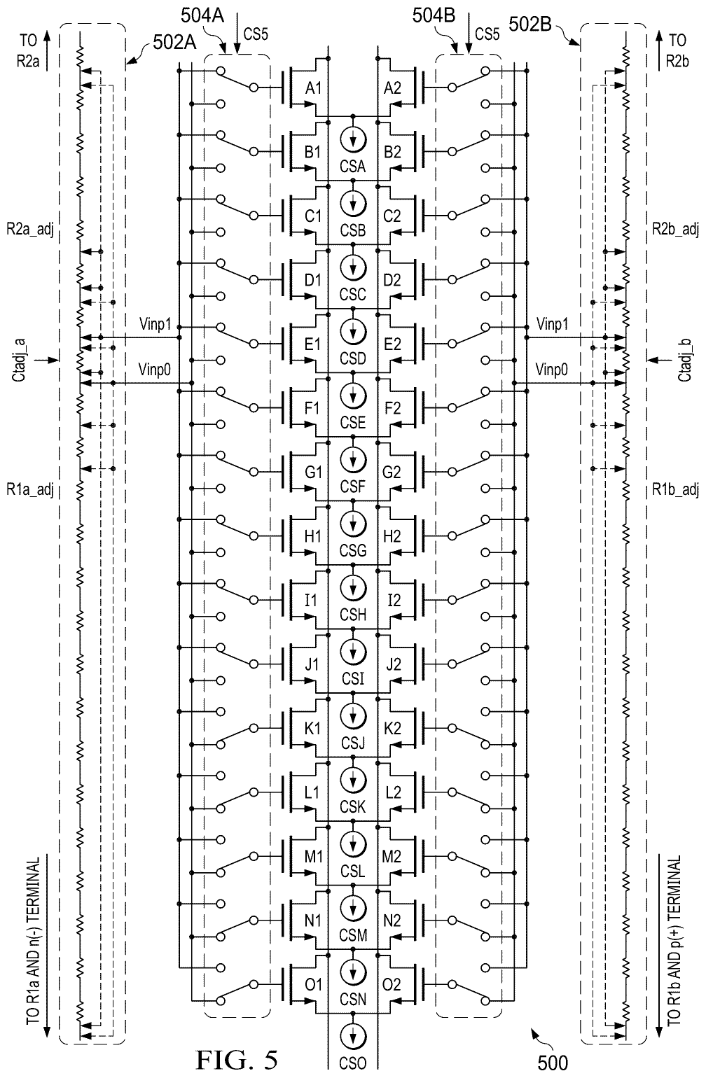

FIG. 5 is a schematic diagram showing example gain trim circuitry 500. In the example of FIG. 5, the gain trim circuitry 500 includes a first resistive network 502A, a second resistive network 502B, a first switch network 504A, a second switch network 504B, first differential input transistor pairs A1/A2 to O1/O2, and current sources CSA to CSO in the arrangement shown. The first resistive network 502A is an example of the resistors R1a_adj and R2a_adj in FIG. 3A, the first resistive network 332 in FIG. 3A, or part of the resistive networks 464 in FIG. 4. The second resistive network 502B is an example of the resistors R1b_adj and R2b_adj in FIG. 3A, the second resistive network 336 in FIG. 3B, or part of the resistive networks 464 in FIG. 4. The first switch network 504A and the second switch network 504B are example components of the first differential input transistor pairs control circuitry 470 in FIG. 4. The first differential input transistor pairs A1/A2 to O1/O2 and the current sources CSA to CSO are gain trim circuitry components (e.g., components of the gain trim circuitry 138 in FIG. 1, components of the gain trim circuitry 238 in FIG. 2, or components of the gain trim circuitry 438 in FIG. 4). In some examples, gain trim circuitry components, such as the gain trim circuitry 500, may include adjustable resistive network components, different differential input transistor pair options, and/or chopper components.

In the example of FIG. 5, the first resistive network 502A receives the control signal Ctadj_a and selects a particular resistor of a chain of series resistors responsive to the control signal Ctadj_a. The second resistive network 502B receives the control signal Ctadj_b and selects a particular resistor of a chain of series resistors responsive to the control signal Ctadj_b. In some examples, the control signals Ctadj_a and Ctadj_b are used to select the same relative resistor position. Once the control signal Ctadj_a selects a resistor in the chain of series resistors of the first resistive network 502A, the resistors above the selected resistor form R2a_adj, and the resistors below the selected resistor form R1a_adj. Similarly, once the control signal Ctadj_b selects a resistor in the chain of series resistors of the second resistive network 502B, the resistors above the selected resistor form R2b_adj, and the resistors below the selected resistor form R1b_adj.

In the example of FIG. 5, the first switch network 504A and the second switch network 504B receive the control signal CS5 described in FIG. 4. Responsive to the control signal CS5, the first switch network 504A and the second switch network 504B couple a group of the first differential input transistor pairs A1/A2 to O1/O2 to the selected resistor pair of the first resistive network 502A and the second resistive network 502B. Once connected, the voltage across the selected resistor of the first resistive network 502A is the difference between Vinn1 and Vinn0. Meanwhile, the voltage across the selected resistor of the second resistive network 502B is the different between Vinp1 and Vinp0.

In some examples, each transistor of the transistor pairs A1/A2 to O1/O2 are sized the same (e.g., the ratio of width/length for each transistor is the same for transistors A1 to O1 and A2 to O2. Also, each of the differential input transistor pairs A1/A2 to O1/O2 is coupled to a respective current source of the current sources CSA to CSO. in some examples, each of the current sources CSA to CSO provides the same current level. In different examples, the number of resistors in the first resistive network 502A and the second resistive network 502B may vary. Also, the number of differential input transistor pairs for the gain trim circuitry 500 may vary.

In the example of FIG. 5, resistor R_adj (R1a_adj and R2a_adj or R1b_adj and R2b_adj herein) is tapped into a differential amplifier. In some examples, the control signals Ctadj_a and Ctadj_b are used to select between a number of resistor taps (e.g., 64=2⁶ resistor taps). In some examples, additional gain steps are provided between the resistor tap steps. Instead of having 1 tap moving on the resistor R_adj, two identical adjacent taps to achieve a target gain value are performed responsive to Ctadj_a and Ctadj_b. For the “p”(+) side, the adjacent taps result in Vinp0 and Vinp1. For the “n”(−) side, the adjacent taps result in Vinn0 and Vinn1. In the example of FIG. 5, the differential input transistor pair of the amplifier is split into multiple parallel transistor pair options. To provide more gain steps, one of the taps is connected to one group of the differential input transistor pairs while the other tap is connected to remaining differential input transistor pairs. In the example of FIG. 5, there are 15 differential input transistor pairs with switches from each differential input transistor pair coupled to the taps connected to the resistors. In some examples, the switches for the first switch network 504A and the second switch network 504B are operated like a “thermometer”. As an example, for a lowest thermometer gain code (e.g., CS5=15′b000 0000 0000 0000), all the diff pairs are connected to the lower Vinn0 tap. At the next code (e.g., CS5=15′b000 0000 0000 0001), one differential input transistor pair is connected to the higher Vinn1 tap while the remaining 14 differential input transistor pairs stay connected to Vinn0. At the next code (e.g., CS5=15′b000 0000 0000 0011), two differential input transistor pairs are connected to Vinn1 while the remaining 13 differential input transistor pairs are connected to the Vinn0 tap. As the control code increases, more differential input transistor pairs are connected to the Vinn1 tap (like a thermometer) and reduce the number of differential input transistor pairs connected to the Vinn0 tap until the last code (e.g., CS5=15′b111 1111 1111 1111) where all the differential input transistor pairs are connected to Vinn1 tap. With the topology of FIG. 5, 16 additional gain step options are provided for each resistor tap step.

In some examples, coarse gain step adjustments may be performed by sliding both the Vinn0 and Vinn1 resistor taps by 1 segment and resetting all the diff pair connections to have them all connected to Vinn0. However, this would create a glitch during this transition. To avoid such glitches, the Vinn1 tap is maintained at the same point and the Vinn0 tap is moved up by 2 segments across the Vinn1 tap while keep the all the differential input transistor pairs connected to the Vinn1 tap. This works because the Vinn0 tap has no differential input transistor pairs connected while the Vinn1 tap with all differential input transistor pairs connected. In some examples, the same resistor tap is done simultaneously for both the first and second resistive networks 502A and 502B to avoid glitches during resistor tap movement. This adjustment technique allows for glitch free resistor tap transitions because all differential input transistor pairs are connected to the Vinn1 (or Vinn0) tap while the Vinn0 (or Vinn1) tap is moved one tap past the Vinn1 (or Vinn0) tap. When moving down, a similar tap sliding technique is performed by moving the outer tap 2 positions down while keeping all differential input transistor pairs connected to the middle tap.

In some examples, combining 16 differential input transistor pair options with 64 gain steps from the resistor taps results in 64×16=1024 gain steps or codes. With coarse trim circuitry, the gain of a differential amplifier gain covers a wider gain range with larger gain step sizes. To improve accuracy (e.g., a 14-bit gain trim), differential amplifier circuitry may include fine gain trim circuitry, which provide fine gain steps to reduce the step size.

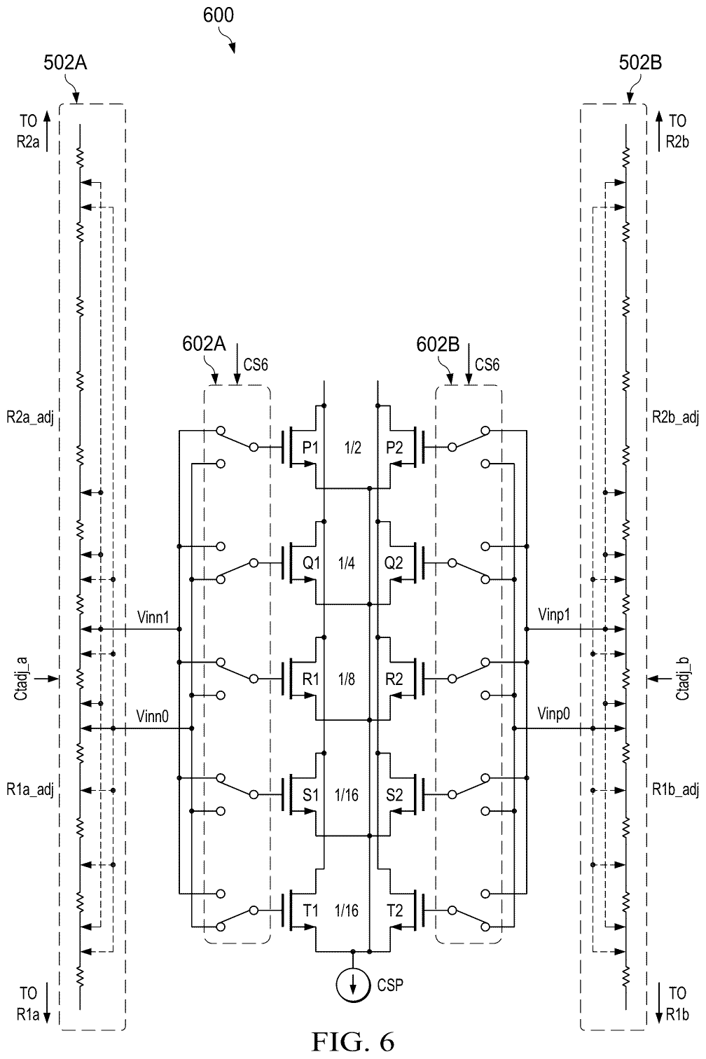

FIG. 6 is a schematic diagram showing other example gain trim circuitry 600. In the example of FIG. 6, the gain trim circuitry 600 includes the first resistive network 502A, the second resistive network 502B, a third switch network 602A, a fourth switch network 602B, second differential input transistor pairs P1/P2 to T1/T2, and current source CSP in the arrangement shown. The first resistive network 502A is an example of the resistors R1a_adj and R2a_adj in FIG. 3A, the first resistive network 332 in FIG. 3B, or part of the resistive networks 464 in FIG. 4. The second resistive network 502B is an example of the resistors R1b_adj and R2b_adj in FIG. 3A, the second resistive network 336, or part of the resistive networks 464 in FIG. 4. The third switch network 602A and the fourth switch network 602B are example components of the second differential input transistor pairs control circuitry 474 in FIG. 4. The second differential input transistor pairs P1/P2 to T1/T2 and the current source CSP are gain trim circuitry components (e.g., components of the gain trim circuitry 138 in FIG. 1, components of the gain trim circuitry 238 in FIG. 2, or components of the gain trim circuitry 438 in FIG. 4). In some examples, gain trim circuitry components, such as the gain trim circuitry 600, may include adjustable resistive network components, different differential input transistor pair options, and/or chopper components.

In the example of FIG. 6, the first resistive network 502A receives the control signal Ctadj_a and selects a particular resistor of a chain of series resistors responsive to the control signal Ctadj_a. The second resistive network 502B receives the control signal Ctadj_a and selects a particular resistor of a chain of series resistors responsive to the control signal Ctadj_a. In some examples, the control signals Ctadj_a and Ctadj_b are used to select the same relative resistor position. Once the control signal Ctadj_a selects a resistor in the chain of series resistors of the first resistive network 502A, the resistors above the selected resistor form R2a_adj, and the resistors below the selected resistor form R1a_adj. Similarly, once the control signal Ctadj_b selects a resistor in the chain of series resistors of the second resistive network 502B, the resistors above the selected resistor form R2b_adj, and the resistors below the selected resistor form R1b_adj.

In the example of FIG. 6, the third switch network 602A and the fourth switch network 602B receive the control signal CS6 described in FIG. 4. Responsive to the control signal CS6, the third switch network 602A and the fourth switch network 602B couple one of the second differential input transistor pairs P1/P2 to T1/T2 to the selected resistor pair of the first resistive network 502A and the second resistive network 502B. Once connected, the voltage across the selected resistor of the first resistive network 502A is the difference between Vinn1 and Vinn0. Meanwhile, the voltage across the selected resistor of the second resistive network 502B is the different between Vinp1 and Vinp0. In some examples, each of the differential input transistor pairs P1/P2 to T1/T2 are sized differently. In the example of FIG. 6, each transistor of differential input transistor pair P1/P2 is ½ the size of each transistor of the differential input transistor pairs A1/A2 to O1/O2 of FIG. 5. Each transistor of differential input transistor pair Q1/Q2 is ¼ the size of each transistor of the differential input transistor pairs A1/A2 to O1/O2 of FIG. 5. Each transistor of the differential input transistor pair R1/R2 is ⅛ the size of each transistor of the differential input transistor pairs A1/A2 to O1/O2. Each transistor of the differential input transistor pair S1/S2 is 1/16 the size of each transistor of the differential input transistor pairs A1/A2 to O1/O2. Each transistor of the differential input transistor pair T1/T2 is 1/16 the size of each transistor of the differential input transistor pairs A1/A2 to O1/O2 of FIG. 5. In some examples, the current sources CSP is shared by all of the differential input transistor pairs P1/P2 to T1/T2. In some examples, the number of differential input transistor pairs for the gain trim circuitry 600 may vary. In some examples, the gain trim circuitry 600 provides fine trim circuitry for a differential amplifier, where each of the differential input transistor pairs provides another fine trim option.

In the example of FIG. 6, 16 additional gain trim steps are interpolated using 5 more differential input transistor pairs. In some examples, the drains of the 5 additional differential input transistor pairs are connected to the same nodes as the differential input transistor pairs that were used for the coarse gain adjustments in FIG. 5. In some examples, the differential input transistor pairs for fine gain trim adjustments share the same current among them with the differential input transistor pairs having respective W/L ratios to provide differential input transistor pair weights of ½, ¼, ⅛, 1/16, and 1/16 of the coarse gain differential input transistor pairs. In some examples, the sum of these W/L ratios is equal to the W/L ratio of the coarse gain differential input transistor pairs. In some examples, the control terminals of the differential input transistor pairs in FIG. 6 are connected to the top tap (Vinn1 or Vinp1) and the bottom tap (Vinn0 or Vinp0) based on a selective binary counting system that produces equal gain steps between codes while minimizing glitches during code transitions. In some examples, the lowest selective binary code would be 5′d1 (e.g., CS6=00001), which results in Vinn1 tap being connected to the T1/T2 differential input transistor pair and results in a W/L weight of 1/16 of a coarse differential input transistor pair. Meanwhile, the Vinn0 tap is connected to the S1/S2, R1/R2, Q1, Q2, and P1/P2 differential input transistor pairs and results in a W/L weight of 15/16 of a coarse differential input transistor pair. The next code is 5′d3 (e.g., CS6=00011), which has A0 and A1 connected to Vin1 and results a weight of 2/16 of a coarse differential input transistor pair and giving Vin0 a weight of 14/16. The next code is 5′d5(e.g., CS6=00101), resulting in the Vin1 tap being weighted at 3/16 of a coarse differential input transistor pair, while the Vin0 tap is weighted at 13/16 of a coarse differential input transistor pair.

In some examples, the selective binary code options include codes for 1, 3, 5, 7, 9, 11, 13, 15, 17, 19, 21, 23, 27, and 31. At code 5′d31(e.g., CS6=11111), the Vinn0 tap has a weight of 0 and the Vinn1 tap is connected to all 5 differential input transistor pairs P1/P2 to T1/T2 and results in a weight of 16/16 or 1 course differential input transistor pair. Accordingly, in some examples, every gain-code increase for fine gain trim adjustments increases the W/L weight by 1/16 relative to the coarse gain trim adjustment. In some examples, glitches are prevented during fine gain trim adjustments when sliding the resistor tap by moving the lower tap by 2 segments up and keeping the higher tap at the same position. In order to continue obtain the same 1/16 W/L weight increments, coarse gain trim steps may be decremented as the gain-code increases. Similarly, selective binary codes may be decremented to avoid glitches. In order to get a 1/16 W/L weight change at the resistor tap transition point, the selective binary code is changed from 5′31(e.g., CS6=5′b11111) to 5′d30 (e.g., CS6=5′b11110). When counting down, the selective binary code options include 30, 28, 26, 24, 22, 20, 18, 16, 14, 12, 10, 8, 6, 4, 2, and 0. In some examples, resistor tap position options, coarse gain trim control options, and fine gain trim control controls options are represented in Table 1.

TABLE 1

| | | | | | Vin0 | Vin0 | | | Vin1 | Vin1 | |
|---|---|---|---|---|---|---|---|---|---|---|---|
| Gain | | | 2nd Trim | Vin0 | 1st | 2nd | | Vin1 | 1st | 2nd | |
| Code | RTC | 1st Trim Code | Code | Pos | W/L Wt | W/L Wt | Vin0 Total Wt | Pos | W/L Wt | W/L Wt | Vin1 Total Wt |
| 0 | 1 | 15′b000000000000000 | 5′b00000 | 1 | 15 | 16/16 | 1 × (15 + 16/16) | 2 | 0 | 0/16 | 2 × (0) |
| 1 | 1 | 15′b000000000000000 | 5′b00001 | 1 | 15 | 15/16 | 1 × (15 + 15/16) | 2 | 0 | 1/16 | 2 × (0 + 1/16) |
| 2 | 1 | 15′b000000000000000 | 5′b00011 | 1 | 15 | 14/16 | 1 × (15 + 14/16) | 2 | 0 | 2/16 | 2 × (0 + 2/16) |
| 15 | 1 | 15′b000000000000000 | 5′b11101 | 1 | 15 | 1/16 | 1 × (15 + 1/16) | 2 | 0 | 15/16 | 2 × (0 + 15/16) |
| 16 | 1 | 15′b000000000000000 | 5′b11111 | 1 | 15 | 0/16 | 1 × (15) | 2 | 0 | 16/16 | 2 × (1) |
| 17 | 1 | 15′b000000000000001 | 5′b00001 | 1 | 14 | 15/16 | 1 × (14 + 15/16) | 2 | 1 | 1/16 | 2 × (1 + 1/16) |
| 18 | 1 | 15′b000000000000001 | 5′b00011 | 1 | 14 | 14/16 | 1 × (14 +14/16) | 2 | 1 | 2/16 | 2 × (1 + 2/16) |
| 31 | 1 | 15′b000000000000001 | 5′b11101 | 1 | 14 | 1/16 | 1 × (14 + 1/16) | 2 | 1 | 15/16 | 2 × (1 + 15/16) |
| 32 | 1 | 15′b000000000000001 | 5′b11111 | 1 | 14 | 0/16 | 1 × (14) | 2 | 1 | 16/16 | 2 × (2) |
| 255 | 1 | 15′b111111111111111 | 5′b11101 | 1 | 0 | 1/16 | 1 × (0 +1/16) | 2 | 15 | 15/16 | 2 × (15 + 15/16) |
| 256 | 1 | 15′b111111111111111 | 5′b11111 | 1 | 0 | 0/16 | 1 × (0) | 2 | 15 | 16/16 | 2 × (15 + 16/16) |
| 257 | 2 | 15′b111111111111111 | 5b11110 | 3 | 0 | 1/16 | 3 × (0 + 1/16) | 2 | 15 | 15/16 | 2 × (15 + 15/16) |
| 258 | 2 | 15′b111111111111111 | 5′b11100 | 3 | 0 | 2/16 | 3 × (0 + 2/16) | 2 | 15 | 14/16 | 2 × (15 + 14/16) |
| 271 | 2 | 15′b111111111111111 | 5′b00010 | 3 | 0 | 15/16 | 3 × (0 + 15/16) | 2 | 15 | 1/16 | 2 × (15 + 1/16) |
| 272 | 2 | 15′b111111111111111 | 5′b00000 | 3 | 0 | 16/16 | 3 × (1) | 2 | 15 | 0/16 | 2 × (15) |
| 273 | 2 | 15′b011111111111111 | 5b11110 | 3 | 1 | 1/16 | 3 × (1 + 1/16) | 2 | 14 | 15/16 | 2 × (14 + 15/16) |
| 511 | 2 | 15′b000000000000000 | 5′b00010 | 3 | 15 | 15/16 | 3 × (15 + 15/16) | 2 | 0 | 1/16 | 2 × (0 + 1/16) |
| 512 | 2 | 15′b000000000000000 | 5′b00000 | 3 | 15 | 16/16 | 3 × (15 + 16/16) | 2 | 0 | 0/16 | 2 × (0) |
| 513 | 3 | 15′b000000000000000 | 5′b00001 | 3 | 15 | 15/16 | 3 × (15 + 15/16) | 4 | 0 | 1/16 | 4 × (0 + 1/16) |
| 514 | 3 | 15′b000000000000000 | 5′b00011 | 3 | 15 | 14/16 | 3 × (15 + 14/16) | 4 | 0 | 2/16 | 4 × (0 + 2/16) |
| 16382 | 64 | 15′b000000000000000 | 5′b00010 | 65 | 15 | 15/16 | 65 × (15 + 15/16) | 64 | 0 | 1/16 | 64 × (0 + 1/16) |
| 16383 | 64 | 15′b000000000000000 | 5′b00000 | 65 | 15 | 16/16 | 65 × (15 + 16/16) | 64 | 0 | 0/16 | 64 × (0) |

In the example of Table 1, 16384 gain steps (e.g., the first column in Table 1) and related gain codes are represented. Each gain step includes a resistor tap code (RTC) (the second column in Table 1), a 1^{st} trim code (e.g., the third column in Table 1), and a 2^{nd} trim code (e.g., the fourth column in Table 1), where the 1^{st} trim code is a coarse trim code, and the second 2^{nd} trim code is a fine trim code. Table 1 also shows Vin0 tap positions due to each resistor tap code (e.g., the fifth column in Table 1), Vin0 tap weights due to each 1^{st} trim code (e.g., the sixth column in Table 1), and Vin0 tap weights due to each 2^{st} trim code (e.g., the seventh column in Table 1), and Vin0 tap total weights due to 1^{st} and 2^{nd} trim codes (e.g., the eighth column in Table 1). Table 1 also shows Vin1 tap positions due to each resistor tap code (e.g., the ninth column in Table 1), Vin1 tap weights due to each 1^{st} trim code (e.g., the tenth column in Table 1), Vin1 tap weights due to each 2^{st} trim code (e.g., the eleventh column in Table 1), and Vin1 tap total weights due to 1^{st} and 2^{nd} trim codes (e.g., the twelfth column in Table 1). With the gain trim technique related to Table 1, a wide gain range and fine resolution is achieved. In the example of Table 1, there are 64 resistor tap options (representing 6 bits of gain trim options), 16 1^{st} trim code options (representing 4 bits of gain trim options), and 16 2^{nd} trim code options (representing 4 bits of gain trim options), resulting in 64×16×16=16384 gain steps or a 14-bit gain adjustment resolution. In other examples, the number of gain steps and/or the gain adjustment resolution may vary.

FIG. 7 is a diagram showing example differential amplifier circuitry 700. In the example of FIG. 7, the differential amplifier circuitry 700 is a chopper amplifier. As shown, the differential amplifier circuitry 700 includes the first resistive network 502A, the second resistive network 502B, first cross-coupled switches 702, second cross-coupled switches 712, a first gain stage 722, third cross-coupled switches 740, a notch filter 750, a second gain stage 760, a feed-forward gain stage 780, a third gain stage 792, and capacitors C1 to C4 in the arrangement shown. Each of the capacitors C1 to C4 has a respective first terminal and a respective second terminal. The first cross-coupled switches 702 has a first terminal 704, a second terminal 706, a third terminal 708, a fourth terminal 710, and a fifth terminal 711. The second cross-coupled switches 712 has a first terminal 714, a second terminal 716, a third terminal 718, a fourth terminal 720, and a fifth terminal 721. The first gain stage 722 has a first terminal 724, a second terminal 726, a third terminal 728, a fourth terminal 730, a fifth terminal 732, a sixth terminal 734, and seventh terminals 736. The first gain stage 722 includes gain trim circuitry 738. In some examples, the gain trim circuitry 738 includes course gain trim circuitry (e.g., the gain trim circuitry 500 in FIG. 5) and fine gain trim circuitry (e.g., the gain trim circuitry 600 in FIG. 6).

The third cross-coupled switches 740 has a first terminal 742, a second terminal 744, a third terminal 746, a fourth terminal 748, and a fifth terminal 749. The notch filter 750 has a first terminal 752, a second terminal 754, a third terminal 756, a fourth terminal 758, and a fifth terminal 759. The second gain stage 760 has a first terminal 762, a second terminal 764, a third terminal 766, and a fourth terminal 768. The third gain stage 792 has a first terminal 794, a second terminal 796, and a third terminal 798. The feed-forward gain stage 780 has a first terminal 781, a second terminal 782, a third terminal 783, a fourth terminal 784, a fifth terminal 785, a sixth terminal 786, and seventh terminals 787. The feed-forward gain stage 780 includes gain trim circuitry 788. The control logic 790 has first terminals 791A, second terminals 791B, a third terminal 791C, and a fourth terminal 791D.

The first terminal 704 of the first cross-coupled switches 702 is coupled to the first resistive network 502A and receives Vinn1. The second terminal 706 of the first cross-coupled switches 702 is coupled to the second resistive network 502B and receives Vinp1. The third terminal 708 of the first cross-coupled switches 702 is coupled to the first terminal 724 of the first gain stage 722. The fourth terminal 710 of the first cross-coupled switches 702 is coupled to the second terminal 726 of the first gain stage 722. The fifth terminal 711 of the first cross-coupled switches 702 is coupled to the third terminal 791C of the control logic 790.

The first terminal 714 of the second cross-coupled switches 712 is coupled to the first resistive network 502A and receives Vinn0. The second terminal 716 of the second cross-coupled switches 712 is coupled to the second resistive network 502B and receives Vinp0. The third terminal 718 of the second cross-coupled switches 712 is coupled to the third terminal 728 of the first gain stage 722. The fourth terminal 720 of the second cross-coupled switches 712 is coupled to the fourth terminal 730 of the first gain stage 722. The fifth terminal 721 of the second cross-coupled switches 712 is coupled to the third terminal 791C of the control logic 790. The fifth terminal 732 of the first gain stage 722 is coupled to the first terminal 742 of the third cross-coupled switches 740. The sixth terminal 734 of the first gain stage 722 is coupled to the second terminal 744 of the third cross-coupled switches 740. The seventh terminals 736 of the first gain stage 722 are coupled to the first terminals 791A of the control logic 790. The third terminal 746 of the third cross-coupled switches 740 is coupled to the first terminal 752 of the notch filter 750 and the first terminal of the capacitor C1. The fourth terminal 748 of the third cross-coupled switches 740 is coupled to the second terminal 754 of the notch filter 750. The fifth terminal 749 of the third cross-coupled switches 740 is coupled to the third terminal 791C of the control logic 790.

The third terminal 756 of the notch filter 750 is coupled to the first terminal 762 of the second gain stage 760 and the first terminal of the capacitor C2. The fourth terminal 758 of the notch filter 750 is coupled to the second terminal 764 of the second gain stage 760. The fifth terminal 759 of the notch filter 750 is coupled to the fourth terminal 791D of the control logic 790.

The first terminal 781 of the feed-forward gain stage 780 is coupled to the first resistive network 502A and receives Vinn1. The second terminal 782 of the feed-forward gain stage 780 is coupled to the second resistive network 502B and receives Vinp1. The third terminal 783 of the feed-forward gain stage 780 is coupled to the first resistive network 502A and receives Vinn0. The fourth terminal 784 of the feed-forward gain stage 780 is coupled to the second resistive network 502B and receives Vinp0. The fifth terminal 785 of the feed-forward gain stage 780 and the third terminal 766 of the second gain stage are coupled to the first terminal 794 of the third gain stage 792 and the first terminal of the capacitor C3. The sixth terminal 786 of the feed-forward gain stage 780 and the fourth terminal 768 of the second gain stage 760 are coupled to the second terminal 796 of the third gain stage 792 and the first terminal of the capacitor C4. The seventh terminals 787 of the feed-forward gain stage 780 are coupled to the first terminals 791A of the control logic 790. The second terminals 791B of the control logic 790 are coupled to the first resistive network 502A and the second resistive network 502B. The second terminals of the capacitors C1 to C4 are coupled to the third terminal 798 of the third gain stage 792.

In some examples, the differential amplifier circuitry 700 operates to: adjust Vinn1, Vinn0, Vinp1, and Vinp0 responsive to the control signals Ctadj_a and Ctadj_b; and provide VOUT responsive to applied VREF set gain by user or system. In some examples, the gain is given as: gain=((VOUT−VREF)/(VINb−VINa))=((R2+R2_adj)/(R1+R1_adj))=R2S/R1S. The operations of the first cross-coupled switches 702, the second cross-coupled switches 712, the first gain stage 722, the third cross-coupled switches 740, the notch filter 750, the second gain stage 760, the feed-forward gain stage 780, the third gain stage 792, the control logic 790, and the capacitors C1 to C4 are used to provide a target gain accuracy and reduce offset, offset temperature drift, and noise.

More specifically, the first resistive network 502A operates to adjust Vinn1 and Vinn0 responsive to the control signal Ctadj_a. The second resistive network 502B operates to adjust Vinp1 and Vinp0 responsive to the control signal Ctadj_b. The control signals Ctadj_a and Ctadj_b are used to select the same relative resistor position. Once the control signal Ctadj_a selects a resistor in the chain of series resistors of the first resistive network 502A, the resistors above the selected resistor form R2a_adj, and the resistors below the selected resistor form R1a_adj. Similarly, once the control signal Ctadj_b selects a resistor in the chain of series resistors of the second resistive network 502B, the resistors above the selected resistor form R2b_adj, and the resistors below the selected resistor form R1b_adj.

The first cross-coupled switches 702 operate to: receive Vinn1 at the first terminal 704; receive Vinp1 at the second terminal 706; receive ϕ at the fifth terminal 711; provide ainn1 at the third terminal 708 responsive to Vinn1, Vinp1 and ϕ; and provide ainp1 at the fourth terminal 710 responsive to Vinn1, Vinp1, and ϕ. When ϕ is asserted, ainn1=Vinn1 and ainp1=Vinp1. When ϕ is de-asserted, ainn1=Vinp1 and ainp1=Vinn1.

The second cross-coupled switches 712 operate to: receive Vinn0 at the first terminal 714; receive Vinp0 at the second terminal 716; receive ϕ at the fifth terminal 721; provide ainn0 at the third terminal 718 responsive to Vinn0, Vinp0 and ϕ; and provide ainp0 at the fourth terminal 720 responsive to Vinn0, Vinp0, and ϕ. When ϕ is asserted, ainn0=Vinn0 and ainp0=Vinp0. When ϕ is de-asserted, ainn0=Vinp0 and ainp0=Vinn0.

The first gain stage 722 operates to: receive ainn1 at the first terminal 724; receive ainp1 at the second terminal 726; receive ainn0 at the third terminal 728; receive ainp0 at the fourth terminal 730; receive CS5 and CS6 at the seventh terminals 736; provide an output signal aoutn at the fifth terminal 732 responsive to ainn1, ainn0, CS5, CS6, and the operations of the gain trim circuitry 738; and provide an output signal aoutp at the sixth terminal 734 responsive to ainp1, ainp0, CS5, CS6, and the operations of the gain trim circuitry 738.

The third cross-coupled switches 740 operate to: receive aoutn at the first terminal 742; receive aoutp at the second terminal 744; receive ϕ at the fifth terminal 749; provide a first output signal at the third terminal 746 responsive to aoutp, aoutn, and ϕ; and provide a second output signal at the fourth terminal 748 responsive to aoutp, aoutn, and ϕ. When ϕ is asserted, the first output signal is equal to aoutn and the second output signal is equal to aoutp. When ϕ is de-asserted, the first output signal is equal to aoutp and the second output signal is equal to aoutn.

The notch filter 750 operates to: receive the first input signal from the third cross-coupled switches 740 at the first terminal 752; receive the second input signal from the third cross-coupled switches 740 at the second terminal 754; receive clock ϕ+90 at the fifth terminal 759; provide a first filtered output at the third terminal 756 responsive to the first and second input signal and clock at ϕ+90; provide a second filtered output at the fourth terminal 758 responsive to first the second input signal and clock ϕ+90. To summarize, the notch filter 750 receives a differential input signal and provides a filtered differential output signal, which reduces ripple in the signal.

The second gain stage 760 operates to: receive the first filtered output at the first terminal 762; receive the second filtered output at the second terminal 764; provide a first amplified output at the third terminal 766 responsive to the first and second filtered differential output from notch filter; and provide a second amplified output at the fourth terminal 768 responsive to the first and second differential filtered output from notch filter. The second gain stage 760 receives a differential input and provides an amplified differential output based on the differential input.

The feed-forward gain stage 780 operates to: receive vinn1 at the first terminal 781; receive vinp1 at the second terminal 782; receive vinn0 at the third terminal 783; receive vinp0 at the fourth terminal 784; receive CS5 and CS6 at the seventh terminals 787; provide an output signal ffoutn at the fifth terminal 785 responsive to vinn1, vinn0, CS5, CS6, and the operations of the gain trim circuitry 788; and provide an output signal ffoutp at the sixth terminal 786 responsive to vinp1, vinp0, CS5, CS6, and the operations of the gain trim circuitry 788.

The third gain stage operates to: receive the first amplified output and the output signal ffoutn at the first terminal 794; receive the second amplified output and the output signal ffoutp at the second terminal 796; and provide VOUT responsive to first amplified output, the second amplified output, the output signal ffoutn, and the output signal ffoutp. In the example of FIG. 7, the capacitors C1 to C4 are used for compensation of the chopper amplifier operations. Such compensation limits the bandwidth of the operational amplifier for improved stability.

With the gain trim circuitry 738, the gain trim circuitry 788, and chopper components (e.g., the first cross-coupled switches 702, the second cross-coupled switches 712, the third cross-coupled switches 740, the notch filter 750, and the feed-forward gain stage 780), the differential amplifier circuitry 700 provides coarse gain trim options, fine gain trim options, improved accuracy and reduced offset, reduced offset temperature drift, and reduced noise.

Because differential amplifiers have inherent offset from transistor mismatches, using a chopper amplifier architecture as in FIG. 7 (e.g., with an inline switched capacitor notch filter and a parallel feedforward path) can reduce the offset. With a chopper amplifier architecture, the differential inputs (Vinn and Vinp) are swapped on every clock cycle. In the example of FIG. 7, the Vinn1/Vinp1 terminals and the Vinn0/Vinp0 terminals are swapped for the first gain stage 722 in the DC high gain path using the first and second cross-coupled switches 702 and 712 clock phase CD. The output of first gain stage 722 is also swapped (chopped) using the third cross-coupled switches 740 to maintain the first gain stage polarity. The notch filter 750 is connected at the output of the first gain stage after the third cross-coupled switches 740 and is chopped using clock phase ϕ+90 to remove ripple due to chopping. The second gain stage 760 is used to boost the gain of the DC path and to further reduce the offset from the un-chopped feed-forward gain stage 780. In some examples, the first gain stage 722 and the feed-forward gain stage 780 use differential input transistor pairs that are interpolated (as described in FIGS. 5 and 6) at the same time to achieve a target gain adjustment. The third gain stage 792 is an output stage for the differential amplifier circuitry 700. In the example of FIG. 7, gain adjustments are achieved using a combination of resistor tap selection, coarse gain trim selection, and fine gain trim selection integrated into a chopper amplifier. With the example of FIG. 7, gain adjustments are possible over a wide range with high resolution reduce gain error while also minimizing amplifier offset error, offset temperature drift and reduced noise.

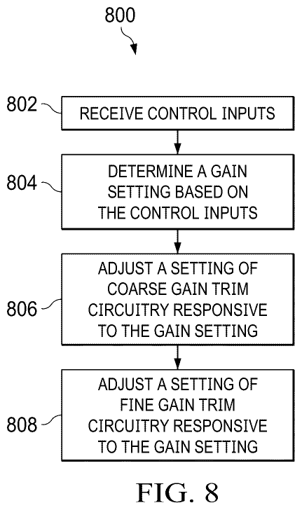

FIG. 8 is a flowchart showing an example gain trim control method 800. The gain trim control method 800 may be performed by control logic of the gain trim circuitry 138 in FIG. 1, control logic of the gain trim circuitry 238 in FIG. 2, the trim controller 320 in FIGS. 3A and 3B, the trim controller 450 in FIG. 4, or control logic 790 in FIG. 7. As shown, the gain trim control method 800 includes receiving control inputs at block 802. At block 804, a gain setting is determined based on the control inputs. At block 806, a setting of coarse gain trim circuitry is adjusted responsive to the gain setting. At block 808, a setting of fine gain trim circuitry is adjusted responsive to the gain setting. In some examples, the operations of block 808 may be performed the operations of block 806. As another option, the operations of blocks 806 and 808 may be performed together or simultaneously. In some examples, the control inputs include a user input and/or gain setting based on programmed or monitored parameters (e.g., an input signal range, a temperature, and/or other monitored parameters). In some examples, differential amplifier circuitry is initially programmed based on room temperature based codes to set the device to have predetermined gain (e.g., 50) at room temperature (˜30C). In some examples, the gain trim control method 800 may include selecting a particular resistor tap code, selecting thermometer code for coarse gain trim adjustment, and selecting a binary code for fine gain trim adjustment. In some examples, the resistor tap code, the thermometer code, and the binary code are converted to respective switch control signals. In some examples, gain trim operations are implemented to have the least possible disturbance at the output of differential amplifier circuitry. Also, gain trim operations are monotonic (each code has a defined output gain and no two codes will give same gain).

In some examples, an integrated circuit includes differential amplifier circuitry (e.g., the differential amplifier circuitry 130 in FIG. 1, the differential amplifier circuitry 230 in FIG. 2, the differential amplifier circuitry 300 in FIG. 3A, the differential amplifier circuitry 350 in FIG. 3B, the differential amplifier circuitry 430 in FIG. 4, or the different amplifier circuitry 700 in FIG. 7). The differential amplifier circuitry includes first gain trim circuitry (e.g., the first input transistor pairs control circuitry 470 in FIG. 4, or the first and second switch networks 504A and 504B in FIG. 5); and second gain trim circuitry (e.g., the second input transistor pairs control circuitry 474 in FIG. 4, or the third and fourth switch networks 602A and 602B in FIG. 5). The first gain trim circuitry has a first gain trim input (e.g., the terminal 472 in FIG. 4, or related terminals in FIG. 5) and includes a first differential input transistor pair (e.g., one of the differential input transistor pairs A1/A2 to O1/O2 in FIG. 5) and a second differential input transistor pair (e.g., another of the differential input transistor pairs A1/A2 to O1/O2 in FIG. 5). The second gain trim circuitry has a second gain trim input (e.g., the terminal 476 in FIG. 4, or related terminals in FIG. 6) and includes a third differential input transistor pair (e.g., one of the differential input transistor pairs P1/P2 to T1/T2 in FIG. 6) and a fourth differential input transistor pair (e.g., another of the differential input transistor pairs P1/P2 to T1/T2 in FIG. 6). The differential amplifier circuitry also includes control logic (e.g., the trim controller 320 in FIGS. 3A and 3B, the trim controller 450 in FIG. 4, or the control logic 790 in FIG. 7) having a first gain trim output (e.g., the second terminal 324 in FIGS. 3A and 3B, the fourth terminal 458 in FIG. 4, one of the first terminals 791A in FIG. 7) and a second gain trim output (e.g., the third terminal 326 in FIGS. 3A and 3B, the fifth terminal 460 in FIG. 4, one of the first terminals 791A in FIG. 7). The first gain trim output is coupled to the first gain trim input. The second gain trim output is coupled to the second gain trim input.

In some examples, each transistor of the first and second differential input transistor pairs has the same W/L ratio. In some examples, the different amplifier circuitry includes a first current source (e.g., one of the current sources CSA to CSO in FIG. 5) and a second current source (e.g., another of the current sources CSA to CSO in FIG. 5). In such examples, the first current source is coupled to the first differential input transistor pair, the second current source is coupled to the second differential input transistor pair, and the first and second current sources are configured to provide the same current level.

In some examples, each transistor of the third differential input transistor pair has a first W/L ratio, and each transistor of the fourth differential input transistor pair has a second W/L ratio that is less than the first W/L ratio. In some examples, the differential amplifier circuitry includes a current source (e.g., the current source CSP in FIG. 6) coupled to the third differential input transistor pair and the fourth differential input transistor pair.

In some examples, the differential amplifier circuitry includes resistive networks (e.g., the resistors in FIG. 3A, the first and second resistive networks 332 and 336 in FIG. 3B, the resistive networks 464 in FIG. 4, the first and second resistive networks 502A and 502B in FIG. 5 to 7). The first gain trim circuitry includes first selection circuitry (e.g., the first and second switch networks 504A and 504B in FIG. 5) coupled between the resistive networks and the first and second differential input transistor pairs. The second gain trim circuitry includes second selection circuitry (e.g., the third and fourth switch networks 602A and 602B in FIG. 6) coupled between the resistive networks and the third and fourth differential input transistor pairs. The first selection circuitry has a first control input (e.g., the terminal 472 in FIG. 4, or related terminals in FIG. 5 to receive the control signal CS5). The second selection circuitry has a second control input (e.g., the terminal 476 in FIG. 4, or related terminals in FIG. 6 to receive the control signal CS6). The first gain trim output is coupled to the first control input. The second gain trim output is coupled to the second control input.

In some examples, the differential amplifier circuitry includes a first gain stage (e.g., the first gain stage 722 in FIG. 7), cross-coupled switches before and after the first gain stage (e.g., the first, second, and third cross-coupled switches 702, 712, and 740 in FIG. 7), and a feed-forward gain stage (e.g., the feed-forward gain stage 780 in FIG. 7). The first gain stage includes the first gain trim circuitry and the second gain trim circuitry (e.g., the first and second gain trim circuitry represented by the gain trim circuitry 738 in FIG. 7). The feed-forward gain stage includes third gain trim circuitry and fourth gain trim circuitry (e.g., the third and fourth gain trim circuitry represented by the gain trim circuitry 788 in FIG. 7). The third gain trim circuitry has a third gain trim input (e.g., the same topology as described for the first gain trim circuitry). The fourth gain trim circuitry having a fourth gain trim input (e.g., the same topology as the second gain trim circuitry. The control logic has a third gain trim output and a fourth gain trim output (e.g., part of the first terminals 791A in FIG. 7). The third gain trim output is coupled to the third gain trim input. The fourth gain trim output is coupled to the fourth gain trim input.

In some examples, the first gain stage includes first input terminals (e.g., the first and second terminals 724 and 726 in FIG. 7), second input terminals (e.g., the third and fourth terminals 728 and 730 in FIG. 7), and first output terminals (e.g., the fifth and sixth terminals 732 and 734). The cross-coupled switches includes first cross-coupled switches (e.g., the first cross-coupled switches 702 in FIG. 7) with second output terminals (e.g., the third and fourth terminals 708 and 710 in FIG. 7), second cross-coupled switches (e.g., the second cross-coupled switches 712 in FIG. 7) with third output terminals (e.g., the third and fourth terminals 718 and 720 in FIG. 7), and third cross-coupled switches (e.g., the third cross-coupled switches 740 in FIG. 7) with third input terminals (e.g., the first and second terminals 742 and 744 in FIG. 7). In such examples, the second output terminals of the first cross-coupling switches are coupled to the first input terminals of the first gain stage. The third output terminals of the second cross-coupled switches are coupled to the second input terminals of the first gain stage. The third input terminals of the third cross-coupled switches are coupled to the first output terminals of the first gain stage.

In some examples, the differential amplifier circuitry includes a notch filter (e.g., the notch filter 750 in FIG. 7), a second gain stage (e.g., the second gain stage 760 in FIG. 7), and a third gain stage (e.g., the third gain stage 792 in FIG. 7). In such examples, the notch filter is configured to filter an output signal from the third cross-coupled switches resulting in a filtered signal. The second gain stage is configured to apply a gain to the filtered signal resulting in an adjusted filtered result. The third gain stage configured to apply a gain to a combination of the adjusted filtered result and an output of the feed-forward gain stage.

In some examples, the control logic is configured to: obtain a first digital code (e.g., the 1^{st} trim code in Table 1); obtain a second digital code (e.g., the 2^{nd} trim code in Table 1); generate a first control signal (e.g., the control signal CS5 herein) at the first gain trim output responsive to the first digital code; and generate a second control (e.g., the control signal CS6 herein) signal at the second gain trim output responsive to the second digital code.

In some examples, a differential amplifier circuit (e.g., the differential amplifier circuitry 130 in FIG. 1, the differential amplifier circuitry 230 in FIG. 2, the differential amplifier circuitry 300 in FIG. 3A, the differential amplifier circuitry 350 in FIG. 3B, the differential amplifier circuitry 430 in FIG. 4, or the different amplifier circuitry 700 in FIG. 7) includes: first differential input transistor pairs (e.g., the differential input transistor pairs A1/A2 to O1/O2 in FIG. 5); second differential input transistor pairs (e.g., the differential input transistor pairs P1/P2 to T1/T2 in FIG. 6); resistive networks (e.g., the resistors in FIG. 3A, the first and second resistive networks 332 and 336 in FIG. 3B, the resistive networks 464 in FIG. 4, the first and second resistive networks 502A and 502B in FIG. 5 to 7); first selection circuitry (e.g., the first input transistor pairs control circuitry 470 in FIG. 4, or first and second switch networks 504A and 504B in FIG. 5) having a first control input (e.g., the terminal 472 in FIG. 4, or related terminals to receive the control signal CS5 in FIG. 5). The first selection circuitry is coupled between the resistive networks and the first differential input transistor pairs. The different amplifier circuitry also includes second selection circuitry (e.g., the second input transistor pairs control circuitry 474 in FIG. 4) having a second control input (e.g., the terminal 476 in FIG. 4, or related terminals to receive the control signal CS6 in FIG. 6). The second selection circuitry is coupled between the resistive networks and the second differential input transistor pairs. The different amplifier circuitry also includes control logic (e.g., the trim controller 320 in FIGS. 3A and 3B, the trim controller 450 in FIG. 4, or the control logic 790 in FIG. 7). The control logic has a first gain trim output (e.g., the second terminal 324 in FIGS. 3A and 3B, the fourth terminal 458 in FIG. 4, or one of the first terminals 791A in FIG. 7) and a second gain trim output (e.g., the third terminal 326 in FIGS. 3A and 3B, the fifth terminal 460 in FIG. 4, or one of the first terminals 791A in FIG. 7). The first gain trim output is coupled to the first control input. The second gain trim output coupled to the second control input.

In some examples, the differential amplifier circuit includes a respective current source (e.g., the current sources CSA to CSO in FIG. 5) coupled to each differential input transistor pair of the first differential input transistor pairs. In such examples, each differential input transistor pair in the first differential input transistor pairs includes transistors with the same W/L ratio, and each respective current source is configured to provide the same current level.

In some examples, the differential amplifier circuit includes a current source (e.g., the current source CSP in FIG. 6) coupled to each differential input transistor pair of the second differential input transistor pairs. In such examples, each differential input transistor pair in the second differential input transistor pairs includes transistors with different W/L ratio.

In some examples, the first differential input transistor pairs, the second differential input transistor pairs, the resistive networks, the first selection circuitry, and the second selection circuitry are part of first gain stage (e.g., the first gain stage 722 in FIG. 7), the resistive networks are first resistive networks, and the differential amplifier circuit further comprises a feed-forward gain stage (e.g., feed-forward gain stage 780 in FIG. 7) including: third differential input transistor pairs (e.g., additional differential input transistor pairs having the topology as the differential input transistor pairs A1/A2 to O1/O2 in FIG. 5); fourth differential input transistor pairs (e.g., additional differential input transistor pairs having the same topology the differential input transistor pairs P1/P2 to T1/T2 as in FIG. 6); second resistive networks (e.g., additional resistive networks having the same topology as the resistors or resistive networks in FIGS. 3A, 3B, and 5 to 7); and third selection circuitry (e.g., another first input transistor pairs control circuitry 470 as in FIG. 4, or additional first and second switch networks 504A and 504B as in FIG. 5). The third selection circuitry has a third control input (e.g., another terminal 472 as in FIG. 4, or related terminals to receive the control signal CS5 as in FIG. 5) coupled to the first gain trim output. The third selection circuitry is coupled between the second resistive networks and the third differential input transistor pairs. The feed-forward gain stage also includes fourth selection circuitry (e.g., another second input transistor pairs control circuitry 474 as in FIG. 4, or additional third and fourth switch networks 602A and 602B as in FIG. 6). The fourth selection circuitry has a fourth control input (e.g., another terminal 476 as in FIG. 4, or related terminals to receive the control signal CS5 as in FIG. 5) coupled to the second gain trim output. The fourth selection circuitry is coupled between the second resistive networks and the fourth differential input transistor pairs.

In some examples, the first gain stage includes first input terminals (e.g., the first and second terminals 724 and 726 in FIG. 7), second input terminals (e.g., the third and fourth terminals 728 and 730 in FIG. 7), and first output terminals (e.g., the fifth and sixth terminals 732 and 734). In such examples, the differential amplifier circuitry includes first cross-coupled switches (e.g., the first cross-coupled switches 702 in FIG. 7) with second output terminals (e.g., the third and fourth terminals 708 and 710 in FIG. 7), second cross-coupled switches (e.g., the second cross-coupled switches 712 in FIG. 7) with third output terminals (e.g., the third and fourth terminals 718 and 720 in FIG. 7), and third cross-coupled switches (e.g., the third cross-coupled switches 740 in FIG. 7) with third input terminals (e.g., the first and second terminals 742 and 744 in FIG. 7). In such examples, the second output terminals of the first cross-coupling switches may be coupled to the first input terminals of the first gain stage. The third output terminals of the second cross-coupled switches may be coupled to the second input terminals of the first gain stage. The third input terminals of the third cross-coupled switches may be coupled to the first output terminals of the first gain stage. In some examples, the differential amplifier circuitry also includes a notch filter (e.g., the notch filter 750 in FIG. 7), a second gain stage (e.g., the second gain stage 760 in FIG. 7), and a third gain stage (e.g., the third gain stage 792 in FIG. 7). In such examples, the notch filter is configured to filter an output signal from the third cross-coupled switches resulting in a filtered signal. The second gain stage is configured to apply a gain to the filtered signal resulting in an adjusted filtered result. The third gain stage configured to apply a gain to a combination of the adjusted filtered result and an output of the feed-forward gain stage.

In some examples, an apparatus (e.g., system 100 in FIG. 1, system 200 in FIG. 2, or related ICs 120 or 220 herein) include differential amplifier circuitry (e.g., the differential amplifier circuitry 130 in FIG. 1, the differential amplifier circuitry 230 in FIG. 2, the differential amplifier circuitry 300 in FIG. 3A, the differential amplifier circuitry 350 in FIG. 3B, the differential amplifier circuitry 430 in FIG. 4, or the different amplifier circuitry 700 in FIG. 7). The differential amplifier circuitry includes first gain trim circuitry (e.g., the first input transistor pairs control circuitry 470 in FIG. 4, or the first and second switch networks 504A and 504B in FIG. 5); second gain trim circuitry (e.g., the second input transistor pairs control circuitry 474 in FIG. 4, or the third and fourth switch networks 602A and 602B in FIG. 5); and control logic (e.g., the trim controller 320 in FIGS. 3A and 3B, the trim controller 450 in FIG. 4, or the control logic 790 in FIG. 7) coupled to the first gain trim circuitry and the second gain trim circuitry. The control logic is configured to: receive control inputs (e.g., IN_P as in FIG. 3A, 3B, or 4); determine a gain setting (e.g., one of the gain codes in Table 1) based on the control inputs; adjust a setting (e.g., by application of the control signal CS5) of the first gain trim circuitry responsive to the gain setting; and adjust a setting (e.g., by application of the control signal CS6) of the second gain trim circuitry responsive to the gain setting.

In some examples, the control inputs include a gain setting selected by a user. In some examples, the control inputs include a temperature. In some examples, the apparatus includes: a device (e.g., the device 102 in FIG. 1, or the electrical device 202 in FIG. 2) coupled to the differential amplifier circuitry; and a controller (e.g., the controller 140 in FIG. 1, or the controller 240 in FIG. 2). coupled to the differential amplifier circuitry and the device. The device is configured to: receive a control signal (e.g., the control signal CS1 in FIG. 1, or the control signal CS2 in FIG. 2) from the controller; perform operations responsive to the control signal; and provide a sense signal (e.g., voltage or current sense signal at the first terminal 104 and/or the second terminal 106 in FIG. 1, or at the first terminal 204 and/or second terminal 206 in FIG. 2). The differential amplifier circuitry is configured to: receive the sense signal; and provide an amplified sense signal (e.g., S1_ISNS in FIG. 1, S2_ISNS in FIG. 2) responsive to the setting of the first gain trim circuitry and the second gain trim circuitry. The controller is configured to: receive the amplified sense signal; and provide the control signal responsive to the amplified sense signal. In different examples, the device of the apparatus may be a motor, a sensor, or another device.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. An integrated circuit comprising:
differential amplifier circuitry including:
first gain trim circuitry having a first gain trim input, the first gain trim circuitry including a first differential input transistor pair and a second differential input transistor pair;
second gain trim circuitry having a second gain trim input, the second gain trim circuitry including a third differential input transistor pair and a fourth differential input transistor pair; and
control logic having a first gain trim output and a second gain trim output, the first gain trim output coupled to the first gain trim input, and the second gain trim output coupled to the second gain trim input.

2. The integrated circuit of claim 1, wherein each transistor of the first and second differential input transistor pairs has the same width-to-length (W/L) ratio.

3. The integrated circuit of claim 2, wherein the different amplifier circuitry includes a first current source and a second current source, the first current source coupled to the first differential input transistor pair, the second current source coupled to the second differential input transistor pair, and the first and second current sources configured to provide the same current level.

4. The integrated circuit of claim 1, wherein each transistor of the third differential input transistor pair has a first width-to-length (W/L) ratio, and each transistor of the fourth differential input transistor pair has a second W/L ratio that is less than the first W/L ratio.

5. The integrated circuit of claim 4, wherein the different amplifier circuitry includes a current source coupled to the third differential input transistor pair and the fourth differential input transistor pair.

6. The integrated circuit of claim 4, wherein the differential amplifier circuitry includes resistive networks, the first gain trim circuitry includes first selection circuitry coupled between the resistive networks and the first and second differential input transistor pairs, the second gain trim circuitry includes second selection circuitry coupled between the resistive networks and the third and fourth differential input transistor pairs, the first selection circuitry having a first control input, the second selection circuitry having a second control input, the first gain trim output coupled to the first control input, and the second gain trim output coupled to the second control input.

7. The integrated circuit of claim 1, wherein the differential amplifier circuitry includes a first gain stage, cross-coupled switches before and after the first gain stage, and a feed-forward gain stage, the first gain stage including the first gain trim circuitry and the second gain trim circuitry, and the feed-forward gain stage including third gain trim circuitry and fourth gain trim circuitry, the third gain trim circuitry having a third gain trim input, the fourth gain trim circuitry having a fourth gain trim input, the control logic having a third gain trim output and a fourth gain trim output, the third gain trim output coupled to the third gain trim input, and the fourth gain trim output coupled to the fourth gain trim input.

8. The integrated circuit of claim 7, wherein the first gain stage includes first input terminals, second input terminals, and first output terminals, the cross-coupled switches includes first cross-coupled switches with second output terminals, second cross-coupled switches with third output terminals, and third cross-coupled switches with third input terminals, the second output terminals of the first cross-coupling switches coupled to the first input terminals of the first gain stage, the third output terminals of the second cross-coupled switches coupled to the second input terminals of the first gain stage, and the third input terminals of the third cross-coupled switches coupled to the first output terminals of the first gain stage.

9. The integrated circuit of claim 8, wherein the differential amplifier circuitry includes a notch filter, a second gain stage, and a third gain stage, the notch filter configured to filter an output signal from the third cross-coupled switches resulting in a filtered signal, the second gain stage configured to apply a gain to the filtered signal resulting in an adjusted filtered result, and the third gain stage configured to apply a gain to a combination of the adjusted filtered result and an output of the feed-forward gain stage.

10. The integrated circuit of claim 8, wherein the control logic is configured to:
obtain a first digital code;
obtain a second digital code;
generate a first control signal at the first gain trim output responsive to the first digital code; and
generate a second control signal at the second gain trim output responsive to the second digital code.

11. A differential amplifier circuit comprising:
first differential input transistor pairs;
second differential input transistor pairs;
resistive networks;
first selection circuitry having a first control input, the first selection circuitry coupled between the resistive networks and the first differential input transistor pairs;
second selection circuitry having a second control input, the second selection circuitry coupled between the resistive networks and the second differential input transistor pairs; and
control logic having a first gain trim output and a second gain trim output, the first gain trim output coupled to the first control input, and the second gain trim output coupled to the second control input.

12. The differential amplifier circuit of claim 11, further comprising a respective current source coupled to each differential input transistor pair of the first differential input transistor pairs, wherein each differential input transistor pair in the first differential input transistor pairs includes transistors with the same width-to-length (W/L) ratio, and each respective current source is configured to provide the same current level.

13. The differential amplifier circuit of claim 11, further comprising a current source coupled to each differential input transistor pair of the second differential input transistor pairs, wherein each differential input transistor pair in the second differential input transistor pairs includes transistors with different width-to-length (W/L) ratio.

14. The differential amplifier circuit of claim 11, wherein the first differential input transistor pairs, the second differential input transistor pairs, the resistive networks, the first selection circuitry, and the second selection circuitry are part of first gain stage, the resistive networks are first resistive networks, and the differential amplifier circuit further comprises a feed-forward gain stage including:
third differential input transistor pairs;
fourth differential input transistor pairs;
second resistive networks;
third selection circuitry having a third control input coupled to the first gain trim output, the third selection circuitry coupled between the second resistive networks and the third differential input transistor pairs; and
fourth selection circuitry having a fourth control input coupled to the second gain trim output, the fourth selection circuitry coupled between the second resistive networks and the fourth differential input transistor pairs.

15. The differential amplifier circuit of claim 14, wherein the first gain stage includes first input terminals, second input terminals, and first output terminals, the differential amplifier circuit further comprising first cross-coupled switches having second output terminals, second cross-coupled switches having third output terminals, and third cross-coupled switches having third input terminals, a notch filter, a second gain stage, and a third gain stage, the notch filter configured to filter an output signal from the third cross-coupled switches resulting in a filtered result, the second gain stage is configured to apply a gain to the second output signal resulting in an adjusted filtered result, and the third gain stage is configured to apply a gain to a combination of the adjusted filtered result and an output of the feed-forward gain stage.

16. An apparatus comprising:
differential amplifier circuitry including:
first gain trim circuitry;
second gain trim circuitry; and
control logic coupled to the first gain trim circuitry and the second gain trim circuitry, the control logic configured to:
receive control inputs;
determine a gain setting based on the control inputs;
adjust a setting of the first gain trim circuitry responsive to the gain setting; and
adjust a setting of the second gain trim circuitry responsive to the gain setting.

17. The apparatus of claim 16, wherein the control inputs include a gain setting selected by a user.

18. The apparatus of claim 16, wherein the control inputs include a temperature.

19. The apparatus of claim 16, further comprising:
a device coupled to the differential amplifier circuitry; and
a controller coupled to the differential amplifier circuitry and the device,
the device configured to:
receive a control signal from the controller;
perform operations responsive to the control signal; and
provide a sense signal,
the differential amplifier circuitry configured to:
receive the sense signal; and
provide an amplified sense signal responsive to the setting of the first gain trim circuitry and the second gain trim circuitry, and
the controller configured to:
receive the amplified sense signal; and
provide the control signal responsive to the amplified sense signal.

20. The apparatus of claim 19, wherein the device is a motor.
